(19) United States
(12) Patent Application Publication
(10) Pub. No.: US 2026/0150524 A1
(43) Pub. Date: May 28, 2026

(54) DISPLAY APPARATUS

(71) Applicant: LG Display Co., Ltd., Seoul (KR)

(72) Inventors: Hoonsok SON, Paju-si (KR); Minki KIM, Paju-si (KR)

(73) Assignee: LG Display Co., Ltd., Seoul (KR)

(21) Appl. No.: 19/178,642

(22) Filed: Apr. 14, 2025

(30) Foreign Application Priority Data
May 23, 2024 (KR) 10-2024-0066965

(51) Int. Cl. H10K 59/123; H10K 59/121; H10K 59/124; H10K 102/00

(52) U.S. Cl. CPC H10K 59/123; H10K 59/1213; H10K 59/124; H10K 2102/351

(57) ABSTRACT

A display apparatus can include a substrate having a first sub-pixel, a second sub-pixel, and a third sub-pixel, a reflective electrode layer including a first reflective electrode of the first sub-pixel, a second reflective electrode of the second sub-pixel, and a third reflective electrode of the third sub-pixel, and an anode electrode layer including a first anode electrode of the first sub-pixel, a second anode electrode of the second sub-pixel, and a third anode electrode of the third sub-pixel. A total thickness of the first reflective electrode and the first anode electrode is equal to a total thickness of the second reflective electrode and the second anode electrode, and is equal to a total thickness of the third reflective electrode and the third anode electrode.

### CROSS-REFERENCE TO RELATED APPLICATION

The present application claims priority to Korean Patent Application No. 10-2024-0066965, filed in the Republic of Korea on May 23, 2024, the entire contents of which are hereby expressly incorporated by reference into the present application.

### BACKGROUND OF THE DISCLOSURE

### Technical Field

The present disclosure relates to a display apparatus.

### Discussion of the Related Art

As the information society develops, various demands for display apparatuses for displaying images are increasing. Various types of display apparatuses such as liquid crystal display (LCD) apparatuses and organic light emitting diode (OLED) display apparatuses are utilized.

Among the display apparatuses, there is an advantage in that the OLED display apparatus as the self-luminous types has superior viewing angles and contrast ratios, and can be lighter and thinner and has low power consumption because it does not require a separate backlight than the LCD apparatus. In addition, there is an advantage in that the OLED displays can drive at a low direct current voltage, have a fast response speed, and especially low manufacturing costs.

Recently, demand for a display apparatus that requires augmented reality (AR), virtual reality (VR), or equivalent ultra-high resolution using such an OLED display apparatus is increasing.

### SUMMARY OF THE DISCLOSURE

The present disclosure is directed to providing a display apparatus in which it is possible to reduce a lateral leakage current by equally maintaining a depth of a trench of each sub-pixel and separating a common light-emitting layer.

The present disclosure is also directed to providing a display apparatus in which an emission area is expanded by expanding an emission area of each sub-pixel to an area in which a trench is disposed.

The present disclosure is also directed to providing a display apparatus which has the micro-cavity characteristic by adjusting thicknesses of a reflective electrode and an anode electrode of each sub-pixel.

Objects of the present disclosure are not limited to the above-described objects, and other technical objects can be inferred from the following embodiments of the present disclosure.

According to one or more embodiments of the present disclosure, there is provided a display apparatus including a substrate including a first sub-pixel, a second sub-pixel, and a third sub-pixel, a reflective electrode layer including a first reflective electrode of the first sub-pixel, a second reflective electrode of the second sub-pixel, and a third reflective electrode of the third sub-pixel, and an anode electrode layer including a first anode electrode of the first sub-pixel, a second anode electrode of the second sub-pixel, and a third anode electrode of the third sub-pixel, wherein a total thickness of the first reflective electrode and the first anode electrode is equal to each of a total thickness of the second reflective electrode and the second anode electrode and a total thickness of the third reflective electrode and the third anode electrode.

According to one or more embodiments of the present disclosure, there is provided a display apparatus including a substrate in which a first sub-pixel having a first emission area and a first non-emission area is defined, an insulating layer on the substrate, a first thin film transistor of the first sub-pixel inside the insulating layer, a first reflective electrode of the first sub-pixel on the insulating layer, a first anode electrode of the first sub-pixel on the first reflective electrode, and a bank disposed in the first non-emission area on the first anode electrode, wherein the first thin film transistor is disposed in the first emission area.

Detailed matters of other embodiments are included in the detailed description and accompanying drawings.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a plan view of a display apparatus according to one or more embodiments of the present disclosure.

FIG. 2 is a cross-sectional view along line A-A′ in FIG. 1.

FIG. 3 is a cross-sectional view along line B-B′ in FIG. 1.

FIG. 4 is a cross-sectional view along line C-C′ in FIG. 1.

FIG. 5 is a cross-sectional view of an organic light emitting diode (OLED) according to FIG. 2.

FIG. 6 is a cross-sectional view of an OLED according to a modified example of FIG. 2.

FIGS. 7 to 12 are cross-sectional views for each process of a method of manufacturing a display apparatus according to one or more embodiments of the present disclosure.

FIG. 13 is a cross-sectional view of a display apparatus according to another embodiment of the present disclosure.

FIG. 14 is a cross-sectional view of a display apparatus according to still another embodiment of the present disclosure.

FIG. 15 is a cross-sectional view of a display apparatus according to still another embodiment of the present disclosure.

FIG. 16 is a cross-sectional view of a display apparatus according to yet another embodiment of the present disclosure.

### DETAILED DESCRIPTION OF THE EMBODIMENTS

Hereinafter, various embodiments of the present disclosure will be described with reference to the accompanying drawings. In the specification, when a first component (or an area, a layer, a portion, etc.) is described as “on,” “connected,” or “coupled to” a second component, it means that the first component can be directly connected/coupled to the second component or a third component (or additional components) can be disposed therebetween.

The same reference numerals indicate the same components. In addition, in the drawings, thicknesses, proportions, and dimensions of components are exaggerated for effective description of technical contents. The term “and/or” includes all one or more combinations that can be defined by the associated configurations.

Terms such as “first,” “second,” etc. can be used to describe various components, but the components are not limited by the terms. The terms are used only for the purpose of distinguishing one component from another and may not define order or sequence. For example, a first component can be referred to as a second component, and similarly, the second component can also be referred to as the first component without departing from the scopes of the embodiments. The singular includes the plural unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings.

It should be understood that term such as “includes” or “has” is intended to specify the presence of features, numbers, steps, operations, components, parts, or a combination thereof described in the disclosure and does not preclude the presence or addition possibility of one or more other features, numbers, steps, operations, components, parts, or combinations thereof in advance. Further, the term “can” fully encompasses all the meanings and coverages of the term “may” and vice versa.

Now, various embodiments of the present disclosure will be discussed. All the components of each display device according to all embodiments of the present disclosure are operatively coupled and configured.

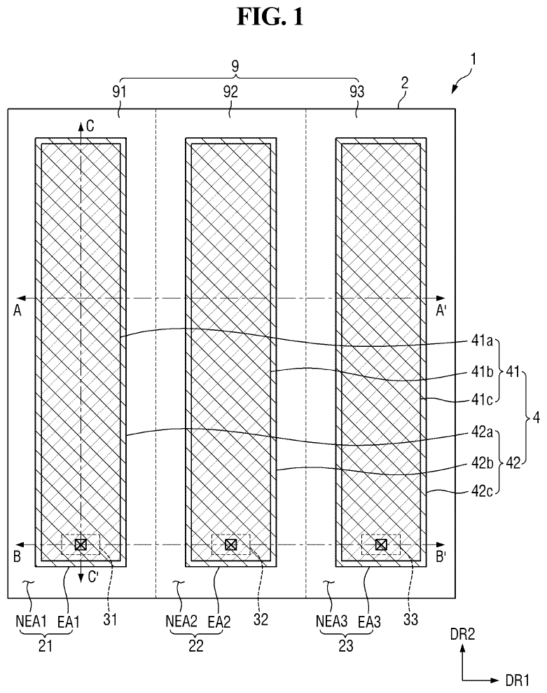

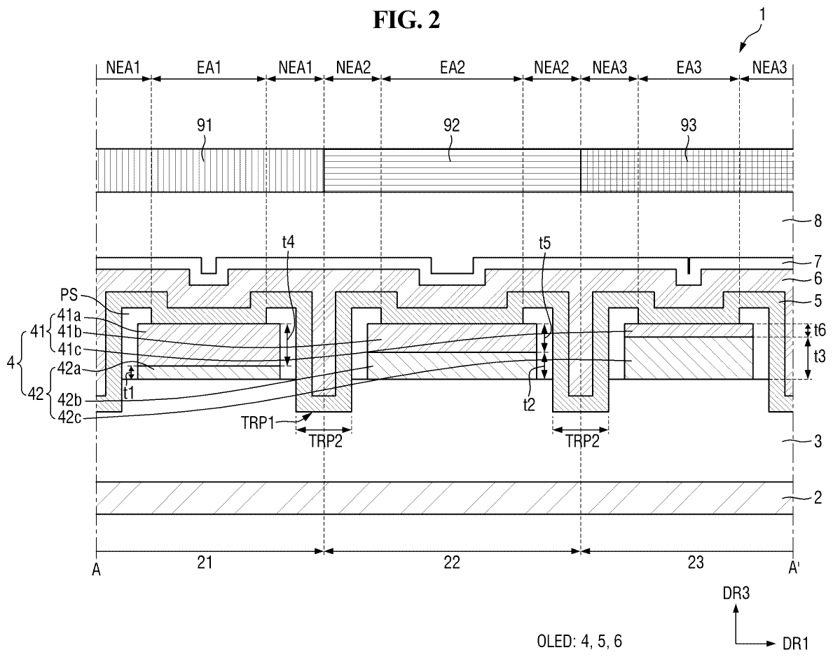

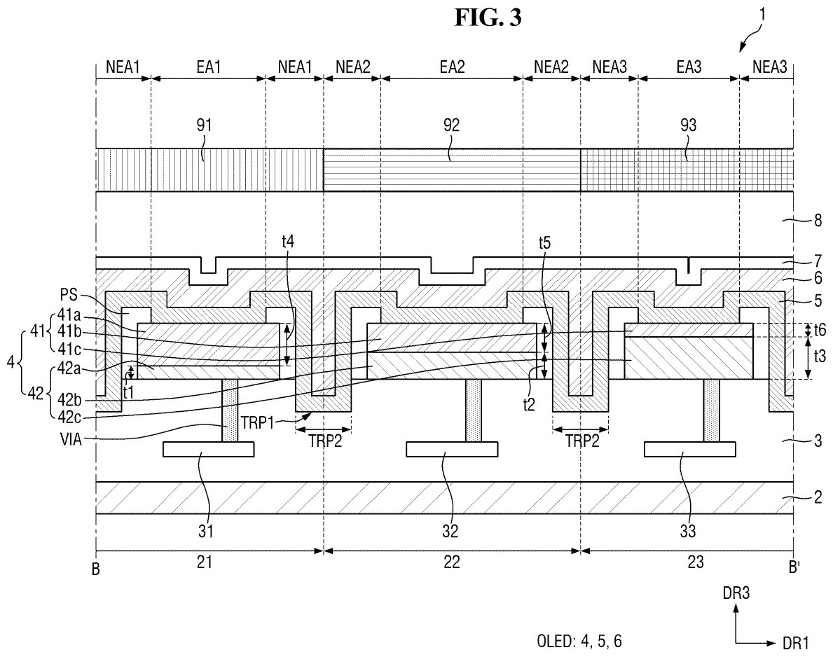

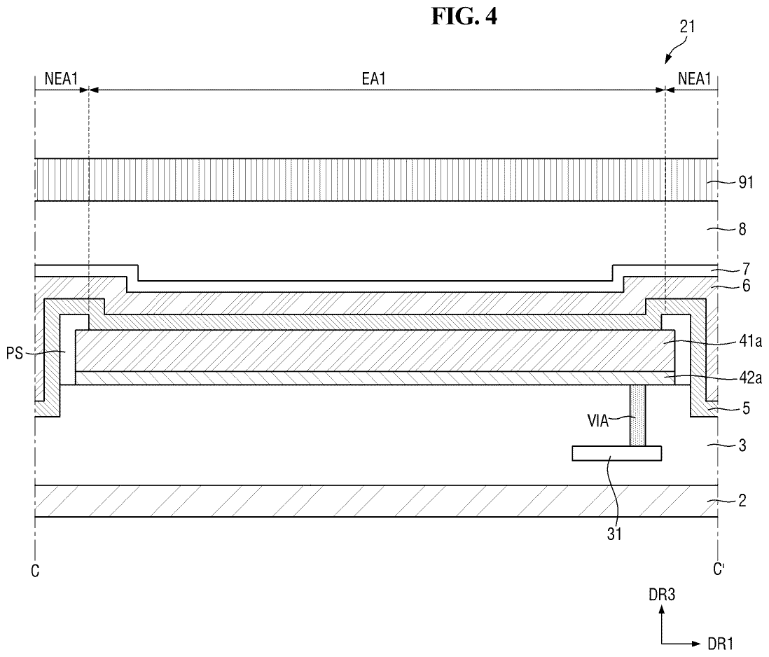

FIG. 1 is a plan view of a display apparatus according to one or more embodiments of the present disclosure. FIG. 2 is a cross-sectional view along line A-A′ in FIG. 1. FIG. 3 is a cross-sectional view along line B-B′ in FIG. 1. FIG. 4 is a cross-sectional view along line C-C′ in FIG. 1.

Referring to FIGS. 1 to 4, a display apparatus 1 according to one or more embodiments includes a substrate 2, a first electrode 4, a common light-emitting layer 5, and a second electrode 6.

A plurality of sub-pixels 21, 22, and 23 are formed on the substrate 2. The plurality of sub-pixels 21, 22, and 23 can form one pixel. The plurality of pixels can be formed on the substrate 2.

The plurality of sub-pixels 21, 22, and 23 include a first sub-pixel 21, a second sub-pixel 22, and a third sub-pixel 23. Since the first sub-pixel 21, the second sub-pixel 22, and the third sub-pixel 23 can be arranged sequentially, the second sub-pixel 22 can be disposed adjacent to one side, for example, the left side of the first sub-pixel 21, and the third sub-pixel 23 can be disposed adjacent to one side, for example, the left side of the second sub-pixel 22.

Throughout the present disclosure, when two sub-pixels are disposed adjacent to each other, it should be construed to mean that no other sub-pixels are disposed between the two sub-pixels.

The first sub-pixel 21 can be provided to emit red (R) light, the second sub-pixel 22 can be provided to emit blue (g) light, and the third sub-pixel 23 can be provided to emit green (B) light, but the embodiments of the present disclosure are not necessarily limited thereto.

FIG. 1 illustrates an example in which a pixel includes only three sub-pixels 21, 22, and 23, but the present disclosure is not limited thereto, and the pixel can include four sub-pixels. When the pixel includes four sub-pixels, the pixel can further include a fourth sub-pixel provided to emit white (W) light.

Each of the first to third sub-pixels 21, 22, and 23 can be provided to have the same size. For example, each of the first to third sub-pixels 21, 22, and 23 can be provided to have the same width and the same height. Here, the width can refer to a horizontal direction (a first direction DR1) based on FIG. 1, and the height can refer to a direction (a second direction DR2) perpendicular to the width based on FIG. 1, but embodiments of the present disclosure are not limited thereto.

Each sub-pixel 21, 22, or 23 can include the emission area EA1, EA2, or EA3 and a non-emission area NEA1, NEA2, or NEA3. The first sub-pixel 21 can include a first emission area EA1 and a first non-emission area NEA1 around the first emission area EA1, the second sub-pixel 22 can include a second emission area EA2 and a second non-emission area NEA2 around the second emission area EA2, and the third sub-pixel 23 can include a third emission area EA3 and a third non-emission area NEA3 around the third emission area EA3. Each emission area EA1, EA2, or EA3 can be the same as an area exposed from a bank PS of a first electrode 4a, 4b, or 4c to be described below.

The first electrode 4 is patterned for each of the sub-pixels 21, 22, and 23. For example, one first electrode 4 is formed in the first sub-pixel 21, another first electrode 4 is formed in the second sub-pixel 22, and still another first electrode 4 is formed in the third sub-pixel 23. The first electrode 4 can serve as an anode of the display apparatus 1. The bank PS (see FIG. 2) to be described below can be disposed on the first electrode 4. The bank PS can be provided to cover an edge of the first electrode 4 disposed in each of the first to third sub-pixels 21, 22, and 23 to distinguish the first sub-pixel 21, the second sub-pixel 22, and the third sub-pixel 23. The first electrode 4 can include an anode electrode 41 and a reflective electrode 42.

The display apparatus 1 can have the reflective electrodes 42 with different surface heights, thereby further increasing light extraction efficiency using the micro-cavity characteristic.

The micro-cavity characteristic refers to a characteristic that, when a distance between the reflective electrode 42 and the second electrode 6 is an integer multiple of a half wavelength (λ/2) of light emitted from the sub-pixels 21, 22 and 23, constructive interference occurs to amplify the light, and when a reflection and re-reflection process is repeated between the reflective electrode 42 and the second electrode 6, a degree of amplified light continuously increases, thereby increasing the external extraction efficiency of light.

The common light-emitting layer 5 can be provided to emit white light. For example, the common light-emitting layer 5 can be provided to emit white light by having a two-stack structure including a blue light-emitting layer, a yellow-green light-emitting layer, and a charge generation layer or a three-stack structure including a blue light-emitting layer, a green light-emitting layer, a red light-emitting layer, and a charge generation layer, but is not necessarily limited thereto, and can be formed of multiple layers exceeding 3 stacks as long as it can emit white light.

The common light-emitting layer 5 can be formed as a common layer across the first to third sub-pixels 21, 22, and 23.

The second electrode 6 is used to form an electric field with the first electrode 4 and can serve as a cathode. The second electrode 6 can be disposed on an upper surface of the common light-emitting layer 5, which is opposite to a lower surface of the common light-emitting layer 5 that comes into contact with the first electrode 4, and provided as a common layer across the first to third sub-pixels 21, 22, and 23. The second electrode 6 can be a cathode electrode.

In the case of the top emission type, the second electrode 6 can be provided as the second electrode, and in the case of the bottom emission type, the second electrode 6 can be provided as the first electrode. In the case of the top emission type, the second electrode 6 can be formed as a translucent electrode to increase light extraction efficiency using the micro-cavity characteristic. Since the display apparatus increases light extraction efficiency using the micro-cavity characteristic in the top emission type, an example in which the second electrode 6 is formed as the translucent electrode will be described.

A color filter layer 9 is provided in each of the first to third sub-pixels 21, 22, and 23 to block a specific color from light emitted from the light-emitting layer 5 of each sub-pixel 21, 22, or 23. A first color filter 91 provided in the first sub-pixel 21 can be provided to block light of other colors excluding red (R) light. In this case, the first color filter 91 can be provided as a red color filter. A second color filter 92 provided in the second sub-pixel 22 can be provided to block light of other colors excluding green (G) light. In this case, the second color filter 92 can be provided as a green color filter. A third color filter 93 provided in the third sub-pixel 23 can be provided to block light of other colors excluding blue (B) light. In this case, the third color filter 93 can be provided as a blue color filter. However, the embodiments of the present disclosure are not limited thereto.

The first to third color filters 91, 92, and 93 provided in the first to third sub-pixels 21, 22, and 23, respectively, can be provided in the same size as the respective sub-pixels or provided by being reduced or expanded at a predetermined ratio to each sub-pixel.

Transistors 31, 32, and 33 can be disposed in the emission areas EA1, EA2, and EA3 of the sub-pixels 21, 22, and 23, respectively. For example, the transistors 31, 32, and 33 can overlap the reflective electrodes 42a, 42b, and 42c disposed in the sub-pixels 21, 22, and 23. The transistors 31, 32, and 33 can be electrically connected to the reflective electrodes 42a, 42b, and 42c, respectively.

Hereinafter, the stacking structure of the display apparatus 1 according to one embodiment will be described in detail.

The display apparatus 1 according to one embodiment includes the substrate 2, the insulating layer 3, the first electrode 4, the bank PS, the common light-emitting layer 5, the second electrode 6, a capping layer 7, an encapsulation layer 8, and the color filter layer 9.

The substrate 2 can be a plastic film, a glass substrate, or a semiconductor substrate, such as silicon.

The substrate 2 can be formed of a transparent material or an opaque material. The first sub-pixel 21, the second sub-pixel 22, and the third sub-pixel 23 are provided on the substrate 2. The first sub-pixel 21 can be provided to emit red (R) light, the second sub-pixel 22 can be provided to emit blue (B) light, and the third sub-pixel 23 can be provided to emit green (G) light.

The display apparatus 1 according to one embodiment is configured in a so-called top emission type in which the emitted light is emitted upward, and thus both a transparent material and an opaque material can be used as a material of the substrate 2. The color filters 91, 92, and 93 can be respectively provided above the first to third sub-pixels 21, 22, and 23 from which light is emitted to transmit light of the above colors.

The insulating layer 3 is formed on the substrate 2. The insulating layer 3 can include an inorganic insulating material.

Circuit elements including a plurality of thin film transistors 31, 32, and 33, various signal lines, capacitors, and the like are provided in the insulating layer 3 of each sub-pixel 21, 22, or 23. The signal lines can include a gate line, a data line, a power line, and a reference line, and the thin film transistors 31, 32, and 33 can include a switching thin film transistor, a driving thin film transistor, and a sensing thin film transistor. Each of the sub-pixels 21, 22, and 23 is defined by an intersection structure of gate lines and data lines. The insulating layer 3 can surround the thin film transistors 31, 32, and 33.

The switching thin film transistor serves to supply the driving thin film transistor with a data voltage switched according to a gate signal supplied to the gate line and supplied from the data line.

The driving thin film transistor functions to generate and supply a data current from the power supplied from the power line to the first electrode 4 by being switched according to the data voltage supplied from the switching thin film transistor.

The sensing thin film transistor serves to detect a threshold voltage deviation of the driving thin film transistor, which causes the degradation of image quality, and supplies the current of the driving thin film transistor to the reference line in response to a sensing control signal supplied from the gate line or a separate sensing line.

The capacitor serves to maintain the data voltage supplied to the driving thin film transistor for one frame and is connected to each of a gate terminal and a source terminal of the driving thin film transistor.

A first thin film transistor 31, a second thin film transistor 32, and a third thin film transistor 33 are disposed in the insulating layer 3 of the sub-pixels 21, 22, and 23, respectively. The first thin film transistor 31 can be connected to the first electrode 4 disposed on the first sub-pixel 21 to apply a driving voltage for emitting light of a color corresponding to the first sub-pixel 21. The first thin film transistor 31, the second thin film transistor 32, and the third thin film transistor 33 can be located on the same thin film transistor layer, but the embodiments of the present disclosure are not limited thereto.

The second thin film transistor 32 can be connected to the first electrode 4 disposed on the second sub-pixel 22 to apply a driving voltage for emitting light of a color corresponding to the second sub-pixel 22.

The third thin film transistor 33 can be connected to the first electrode 4 disposed on the third sub-pixel 23 to apply a driving voltage for emitting light of a color corresponding to the third sub-pixel 23.

When receiving the gate signal from the gate line using each of the transistors 31, 32, and 33, each of the first sub-pixel 21, the second sub-pixel 22, and the third sub-pixel 23 supplies a predetermined current to the light-emitting layer according to the data voltage of the data line. Accordingly, the light-emitting layer of each of the first sub-pixel 21, the second sub-pixel 22, and the third sub-pixel 23 can emit light with a predetermined brightness according to the predetermined current.

The insulating layer 3 can protect the transistors 31, 32, and 33. The insulating layer 3 can be formed of an inorganic insulating material, but is not necessarily limited thereto and can be formed of an organic insulating material. For example, the insulating layer 3 can be formed of an inorganic material, such as silicon nitride (SiNₓ), silicon oxide (SiOₓ), aluminum oxide (Al₂O₃), etc., but the embodiments of the present disclosure are not limited thereto.

A first trench TRP1 can be formed in the insulating layer 3. For example, the first trench TRP1 can be formed in the non-emission areas NEA1, NEA2, and NEA3. The first trench TRP1 can be formed to be recessed downward from an upper surface of the insulating layer 3. Accordingly, a thickness of the insulating layer 3 in which the first trench TRP1 is formed can be smaller than a thickness of the insulating layer 3 in which the first trench TRP1 is not formed.

A first via hole VIA1 can be formed in the insulating layer 3. The first via hole VIA1 can pass through the insulating layer 3 in a thickness direction and can be electrically connected to the transistor 31, 32, or 33 of the sub-pixels 21, 22, or 23. The first via hole VIA1 can include a metal. For example, the first via hole VIA1 can include tungsten, but the embodiments of the present disclosure are not limited thereto. The first via hole VIA1 can be disposed on the emission areas EA1, EA2, and EA3.

A reflective electrode layer can be disposed on the insulating layer 3. The reflective electrode layer can include the reflective electrode 42. The reflective electrode 42 can include a first reflective electrode 42a of the first sub-pixel 21, a second reflective electrode 42b of the second sub-pixel 22, and a third reflective electrode 42c of the third sub-pixel 23. The reflective electrodes 42a, 42b, and 42c can be disposed on the emission areas EA1, EA2, and EA3, respectively, and parts of the reflective electrodes 42a, 42b, and 42c can extend to the non-emission areas NEA1, NEA2, and NEA3, respectively. The reflective electrodes 42a, 42b, and 42c can be disposed on the same layer.

The reflective electrodes 42a, 42b, and 42c can be disposed on the same layer and can include the same material. The reflective electrodes 42a, 42b, and 42c can reflect light, which is emitted toward the reflective electrode 42 among light emitted from the common light-emitting layer 5 of each sub-pixel 21, 22, or 23, toward the second electrode 6 or the encapsulation layer 8. In addition, the reflective electrode 42 is formed to implement the micro-cavity characteristic through reflection and re-reflection with the second electrode 6. To this end, the reflective electrode 42 can include a reflective material for reflecting light. For example, the reflective material can be a metal, but is not necessarily limited thereto, and can be any other material as long as it can reflect light. For example, the reflective material can include aluminum (Al) or silver (Ag), but the embodiments of the present disclosure are not limited thereto. Since the reflective electrode 42 is disposed at a relatively lower location than the common light-emitting layer 5 for emitting light, the reflective electrode 42 can reflect the light emitted from the common light-emitting layer 5 upward. Here, upward can refer to a direction in which a user can perceive light, for example, a side to which the encapsulation layer 8 or the color filter layer 9 is disposed. Accordingly, it is possible to further increase the light efficiency of the first sub-pixel 21, the second sub-pixel 22, and the third sub-pixel 23 compared to a case in which there is no reflective electrode 42, and the user can perceive an image with high brightness, for example, clear image, through the increased light efficiency. For example, the user can perceive a clear image.

As illustrated in FIG. 3, the reflective electrodes 42a, 42b, and 42c can be electrically connected to the thin film transistors 31, 32, and 33 through the first via hole VIA1 in the areas in which the thin film transistors 31, 32, and 33 are disposed. The reflective electrodes 42a, 42b, and 42c can overlap the thin film transistors 31, 32, and 33 in the thickness direction, respectively. The thin film transistors 31, 32, and 33 can be disposed in the emission areas EA1, EA2, and EA3 of the sub-pixels 21, 22, and 23, respectively.

The reflective electrodes 42a, 42b, and 42c can have different thicknesses. For example, a thickness t1 of the first reflective electrode 42a can be smaller than a thickness t2 of the second reflective electrode 42b, and a thickness t3 of the third reflective electrode 42c can be larger than a thickness t2 of the second reflective electrode 42b.

Accordingly, a distance between the first reflective electrode 42a and the second electrode 6 can be longer than a distance between the second reflective electrode 42b and the second electrode 6. A distance between the second reflective electrode 42b and the second electrode 6 can be longer than a distance between the third reflective electrode 42c and the second electrode 6.

In this way, the reason why the reflective electrodes 42a, 42b, and 42c are formed to have various spacing distances (or resonance distances) from the second electrode 6 is that the light extraction efficiency of different colors can be increased through reflection and re-reflection between the reflective electrodes 42a, 42b, and 42c and the second electrode 6 according to the spacing distances. Accordingly, it is possible to increase the light extraction efficiency of red light in the first sub-pixel 21, increase the light extraction efficiency of green light in the second sub-pixel 22, and increase the light extraction efficiency of blue light in the third sub-pixel 23.

The first electrode 4 is patterned for each of the first to third sub-pixels 21, 22, and 23. The first electrode 4 is connected to the driving thin film transistor provided in the insulating layer 3. For example, the first electrode 4 can be electrically connected to the transistors 31, 32, and 33 through the first via hole VIA1.

The first electrode 4 can include the anode electrode 41 on the reflective electrode 42. The anode electrode 41 can include a first anode electrode 41a of the first sub-pixel 21, a second anode electrode 41b of the second sub-pixel 22, and a third anode electrode 41c of the third sub-pixel 23. The anode electrodes 41a, 41b, and 41c can be disposed in an anode electrode layer, disposed on the same layer, and can include the same material.

Each anode electrode 41a, 41b, or 41c can come into direct contact with the upper surface of each reflective electrode 42a, 42b, or 42c. Each anode electrode 41a, 41b, or 41c can have the same width as each reflective electrode 42a, 42b, or 42c, and a side surface of each anode electrode 41a, 41b, or 41c can be aligned with a side surface of each reflective electrode 42a, 42b, or 42c.

Each anode electrode 41a, 41b, or 41c can come into direct contact with each reflective electrode 42a, 42b, or 42c, and each reflective electrode 42a, 42b, or 42c can be electrically connected to the thin film transistor 31, 32, or 33 so that the anode electrode 41a, 41b, or 41c can be electrically connected to the thin film transistor 31, 32, or 33.

For example, the anode electrodes 41a, 41b, and 41c can include a transparent conductive material. For example, the anode electrodes 41a, 41b, and 41c can include ITO, IZO, or TiN, but are not limited thereto.

The anode electrodes 41a, 41b, and 41c can have different thicknesses. For example, a thickness t4 of the first anode electrode 41a can be smaller than a thickness t5 of the second anode electrode 41b, and a thickness t6 of the third anode electrode 41c can be larger than a thickness t5 of the second anode electrode 41b.

For example, a total of the thickness t4 of the first anode electrode 41a and the thickness t1 of the first reflective electrode 42a can be equal to each of a total of the thickness t5 of the second anode electrode 41b and the thickness t2 of the second reflective electrode 42b and a total of the thickness t6 of the third anode electrode 41c and the thickness t3 of the third reflective electrode 42c.

Accordingly, the upper surfaces of the anode electrode 41a, 41b, and 41c can be located colinearly.

The first electrode 4 of each sub-pixel 21, 22, or 23 can be physically separated from the first electrode 4 of the adjacent sub-pixel 21, 22, or 23. A second trench TRP2 can be formed in a spacing space between the first electrodes 4 of adjacent sub-pixels 21, 22, and 23. The second trench TRP2 can be defined by the bank PS disposed in the non-emission NEA1, NEA2, or NEA3 of the first electrode 4 of each sub-pixel 21, 22, or 23.

The total of the thickness t4 of the first anode electrode 41a and the thickness t1 of the first reflective electrode 42a can be equal to each of the total of the thickness t5 of the second anode electrode 41b and the thickness t2 of the second reflective electrode 42b and the total of the thickness t6 of the third anode electrode 41c and the thickness t3 of the third reflective electrode 42c, the anode electrodes 41a, 41b, and 41c can have the same width as the reflective electrodes 42a, 42b, and 42c, respectively, and the side surface of each anode electrode 41a, 41b, or 41c can be aligned with the side surface of each reflective electrode 42a, 42b, or 42c.

Accordingly, the second trenches TRP2 formed between the adjacent sub-pixels 21, 22, and 23 can be formed to have the same thickness. Accordingly, it is possible to reduce a lateral leakage current (LLC) due to the common light-emitting layer 5 between the adjacent sub-pixels 21, 22, and 23.

For example, a width of the second trench TRP2 can be equal to a width of the first trench TRP1, but the embodiments of the present disclosure are not limited thereto.

The banks PS can be disposed on the anode electrodes 41a, 41b, and 41c. The bank PS can be formed of an inorganic material, such as silicon nitride (SiNₓ), silicon oxide (SiOₓ), aluminum oxide (Al₂O₃), etc., but the embodiments of the present disclosure are not limited thereto. The banks PS can be disposed on the non-emission areas NEA1, NEA2, and NEA3.

In the emission areas EA1, EA2, and EA3, the banks PS can expose the upper surfaces of the anode electrodes 41a, 41b, and 41c to define the emission areas EA1, EA2, and EA3. The banks PS can come into direct contact the upper surfaces of the anode electrodes 41a, 41b, and 41c, the side surfaces of the anode electrodes 41a, 41b, and 41c, and the side surfaces of the reflective electrodes 42a, 42b, and 42c. The reflective electrode 42a, 42b, or 42c exposes a part of the upper surface of the insulating layer 3 in which the first trench TRP1 is not formed, and the bank PS can come into direct contact with the upper surface of the insulating layer 3 in which the first trench TRP1 is not formed. An inner surface of the bank PS can come into contact with the side surface of the reflective electrode 42a, 42b, or 42c and the side surface of the anode electrode 41a, 41b, or 41c, and an outer surface of the bank PS can define the second trench TRP2. For example, the second trench TRP2 can be formed in each of a spacing space between an outer surface of the bank PS of the first sub-pixel 21 and an outer surface of the bank PS of the second sub-pixel 22 and a spacing space between the outer surface of the bank PS of the second sub-pixel 22 and an outer surface of the bank PS of the third sub-pixel 23.

A total of the thickness of the first trench TRP1 and the thickness of the second trench TRP2 can be maintained at the same level across all of the non-emission areas NEA1, NEA2, and NEA3 of the display apparatus 1. Accordingly, it is possible to reduce the LLC due to the common light-emitting layer 5 between the adjacent sub-pixels 21, 22, and 23.

In addition, according to the display apparatus 1, it is possible to expand the emission areas EA1, EA2, and EA3 of the sub-pixels 21, 22, and 23 by expanding the emission areas EA1, EA2, and EA3 of the sub-pixels 21, 22, and 23 to the areas in which the thin film transistors 31, 32, and 33 are disposed. To expand the emission areas EA1, EA2, and EA3 of the sub-pixels 21, 22, and 23, the reflective electrodes 42a, 42b, and 42c can all be formed at the same locations. For the above-described micro-cavity characteristic, the reflective electrodes 42a, 42b, and 42c can all be formed at the same locations by adjusting only the thicknesses of the reflective electrodes 42a, 42b, and 42c.

The common light-emitting layer 5 is formed on the first electrode 4 and the bank PS. The common light-emitting layer 5 can come into contact with the upper surface of the first electrode 4. The common light-emitting layer 5 can come into direct contact with the upper surfaces of the anode electrodes 41a, 41b, and 41c, the upper surface and side surface of the bank PS, and the upper surface of the insulating layer 3. The common light-emitting layer 5 can also be formed to extend to the first trench TRP1 and the second trench TRP2.

The OLED according to one embodiment can include the first electrode 4 or ANO, the second electrode 6 or CAT, and the common light-emitting layer 5 between the first electrode 4 and the second electrode 6.

The common light-emitting layer 5 can be provided to emit white (W) light. To this end, the common light-emitting layer 5 can include a plurality of stacks for emitting light of different colors. Specifically, the common light-emitting layer 5 can include a first stack, a second stack, and a charge generation layer CGL provided between the first stack and the second stack.

The second electrode 6 is formed on the common light-emitting layer 5. The second electrode 6 can serve as a cathode of the display apparatus 1. Like the common light-emitting layer 5, the second electrode 6 is formed in each of the sub-pixels 21, 22, and 23 and between the sub-pixels 21, 22, and 23.

In the display apparatus 1 according to one embodiment, the second electrode 6 can be formed as a translucent electrode to implement white light with light efficiency in the top emission type. Accordingly, the micro-cavity effect can be obtained for each of the first to third sub-pixels 21, 22, and 23. As reflection and re-reflection of light are repeated between the second electrode 6 and the reflective electrode 42, it is possible to obtain the micro-cavity effect, thereby increasing light extraction efficiency.

Meanwhile, since the second electrode 6 is formed on the upper surface of the common light-emitting layer 5, the second electrode 6 can be formed along a profile of the common light-emitting layer 5. Since the common light-emitting layer 5 is formed along a profile of the first electrode 4 in the emission area, the second electrode 6 can be formed along the profile of the first electrode 4. In addition, the capping layer 7 on the second electrode 6 can also be formed along a profile of the second electrode 6.

The capping layer 7 can be formed of an inorganic insulating material, but is not limited thereto. The capping layer 7 can be disposed on the second electrode 6 to protect the OLED.

The encapsulation layer 8 is formed on the second electrode 6 to prevent external moisture from penetrating the common light-emitting layer 5. The encapsulation layer 8 can be formed of an inorganic insulating material or formed in a structure in which an inorganic insulating material and an organic insulating material are alternately stacked, but is not necessarily limited thereto.

The color filter layer 9 is formed on the encapsulation layer 8. The color filter layer 9 can include the red (R) first color filter 91 provided in the first sub-pixel 21, the blue (G) second color filter 92 provided in the second sub-pixel 22, and the green (B) third color filter 93 provided in the third sub-pixel 23, but is not necessarily limited thereto.

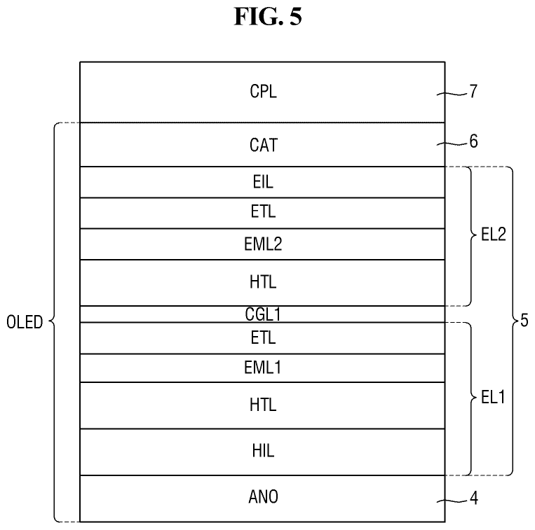

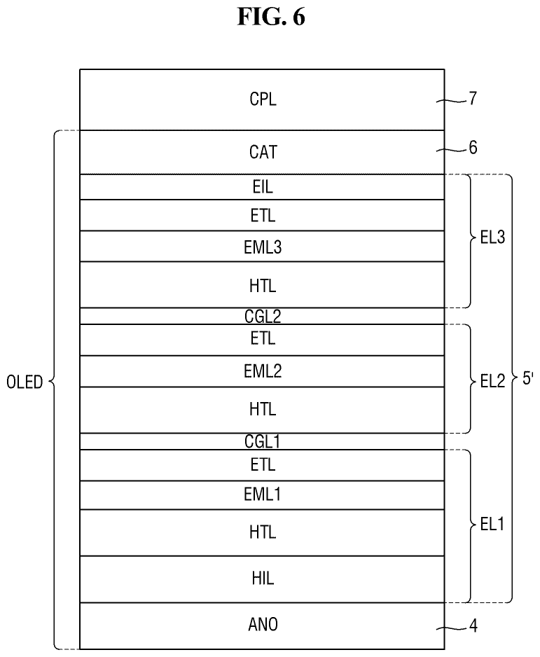

FIG. 5 is a cross-sectional view of an OLED according to FIG. 2. FIG. 6 is a cross-sectional view of an OLED according to a modified example of FIG. 2.

Referring to FIGS. 1 to 5, the common light-emitting layer 5 can include a first stack EL1, a second stack EL2, and a first charge generation layer CGL1, which are provided on the first electrode 4.

The first stack EL1 can be provided on the first electrode 4 and configured in a structure in which a hole injecting layer HIL, a hole transporting layer HTL, a blue (B) emitting layer EML1, and an electron transporting layer (ETL) can be stacked sequentially.

The first stack EL1 can be disposed between the first sub-pixel 21 and the second sub-pixel 22 and between the second sub-pixel 22 and the third sub-pixel 23.

The first charge generation layer CGL1 serves to supply charges to the first stack EL1 and the second stack EL2. The first charge generation layer CGL1 can include an N-type charge generation layer for supplying electrons to the first stack EL1 and a P-type charge generation layer for supplying holes to the second stack EL2. The N-type charge generation layer can include a metal material as a dopant.

The second stack EL2 can be provided on the first stack EL1 and configured in a structure in which a hole transporting layer HTL, a yellow green (YG) emitting layer EML2, an electron transporting layer ETL, and an electron injecting layer EIL are stacked sequentially.

The second stack EL2 can be disposed between the first sub-pixel 21 and the second sub-pixel 22 and between the second sub-pixel 22 and the third sub-pixel 23.

As a result, the common light-emitting layer 5 can be provided as a common layer throughout the first to third sub-pixels 21, 22, and 23 as illustrated in FIGS. 3 and 4.

Referring to FIG. 6, a common light-emitting layer 5′ of the OLED according to one embodiment can include the first stack EL1 provided on the first electrode 4, the second stack EL2, a third stack EL3, the first charge generation layer CGL1 between the first stack EL1 and the second stack EL2, and a second charge generation layer CGL2 between the second stack EL2 and the third stack EL3.

The first stack EL1 can be provided on the first electrode 4 and configured in a structure in which the hole injecting layer HIL, the hole transporting layer HTL, a blue (B) emitting layer EML1, and the electron transporting layer ETL are stacked sequentially.

The first stack EL1 can be disposed between the first sub-pixel 21 and the second sub-pixel 22 and between the second sub-pixel 22 and the third sub-pixel 23, for example, on the bank ps.

The first charge generation layer CGL1 serves to supply charges to the first stack EL1 and the second stack EL2. The first charge generation layer CGL1 can include an N-type charge generation layer for supplying electrons to the first stack EL1 and a P-type charge generation layer for supplying holes to the second stack EL2. The N-type charge generation layer can include a metal material as a dopant.

The second stack EL2 can be provided on the first stack EL1 and configured in a structure in which a hole transporting layer HTL, a green (G) emitting layer EML2, an electron transporting layer ETL are stacked sequentially.

The second stack EL2 can be disposed between the first sub-pixel 21 and the second sub-pixel 22 and disposed between the second sub-pixel 22 and the third sub-pixel 23, for example, on the bank ps.

The second charge generation layer CGL2 serves to supply charges to the second stack EL2 and the third stack EL3. The second charge generation layer CGL2 can include an N-type charge generation layer for supplying electrons to the second stack EL2 and a P-type charge generation layer for supplying holes to the third stack EL3. The N-type charge generation layer can include a metal material as a dopant.

The third stack EL3 can be provided on the second stack EL2 and configured in a structure in which a hole transporting layer HTL, a red (R) emitting layer EML3, an electron transporting layer ETL, and an electron injecting layer EIL are stacked sequentially.

As illustrated in FIGS. 1 to 6, the charge generation layers CGL1 and CGL2 can be disposed between the first sub-pixel 21 and the second sub-pixel 22 and between the second sub-pixel 22 and the third sub-pixel 23. Meanwhile, in the display apparatus 1 according to one embodiment, since the common light-emitting layer 5 is also disposed between the sub-pixels 21, 22, and 23, when one sub-pixel emits light, a lateral leakage current can flow to the adjacent sub-pixels 21, 22, and 23 through the charge generation layers CGL1 and CGL2, but the trenches TRP1 and TRP2 can be formed between the sub-pixels 21, 22, and 23. A formation length of the common light-emitting layer 5 at the boundaries of the sub-pixels 21, 22, and 23 can be increased through the trenches TRP1 and TRP2, thereby increasing a current path. Accordingly, it is possible to prevent the occurrence of the lateral leakage current. Furthermore, the common light-emitting layer 5 can be separated by the trench TRP, thereby preventing the lateral leakage current.

Referring back to FIGS. 2 to 4, the second electrode 6 is formed on the common light-emitting layer 5, the encapsulation layer 8 is formed on the second electrode 6, and the color filter layer 9 is formed on the encapsulation layer 8.

Black matrices for preventing color mixing between the sub-pixels can be provided between the first to third color filters 91, 92, and 93.

Hereinafter, a method of manufacturing a display apparatus according to one or more embodiments will be described. In the description of the following embodiments, the detailed description of components that are the same as or similar to the components described in FIGS. 1 to 6 will be omitted or briefly discussed, or overlapping descriptions thereof will be omitted or briefly discussed.

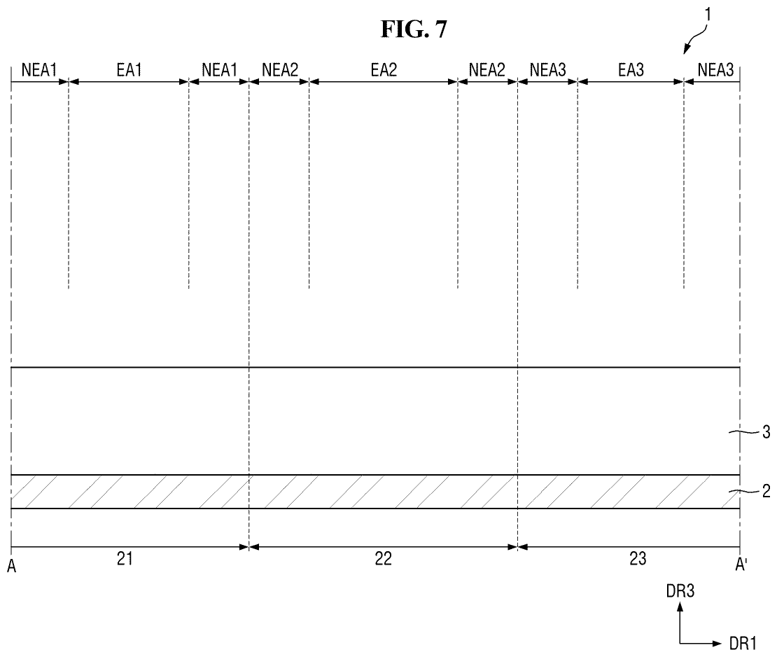

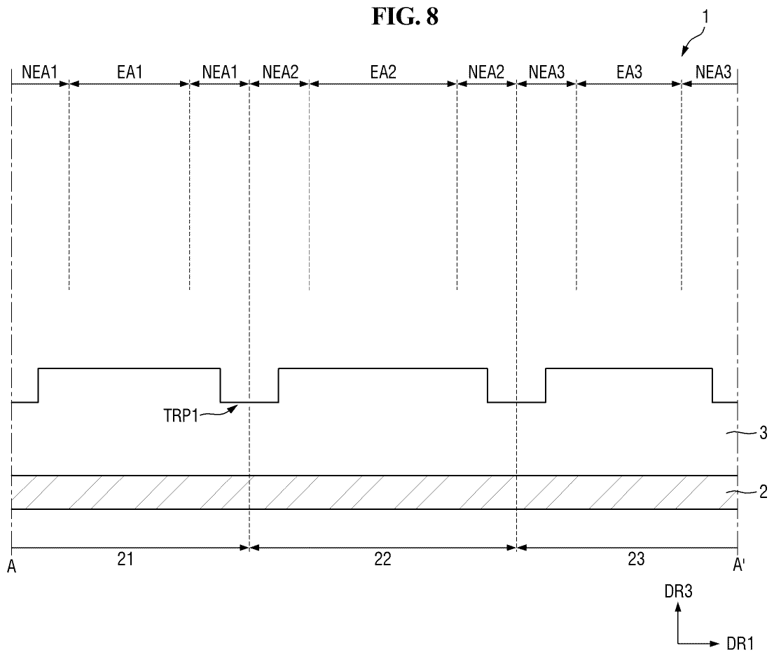

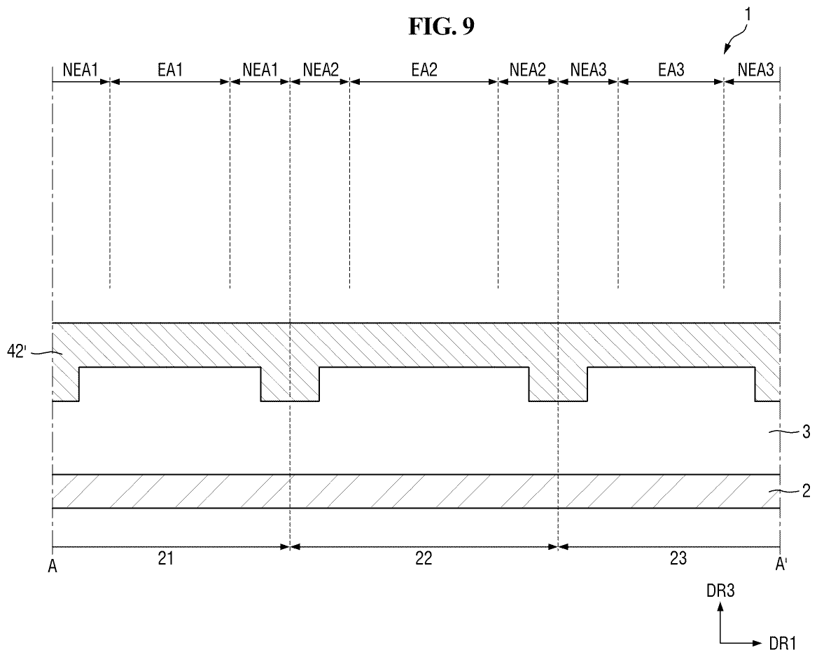

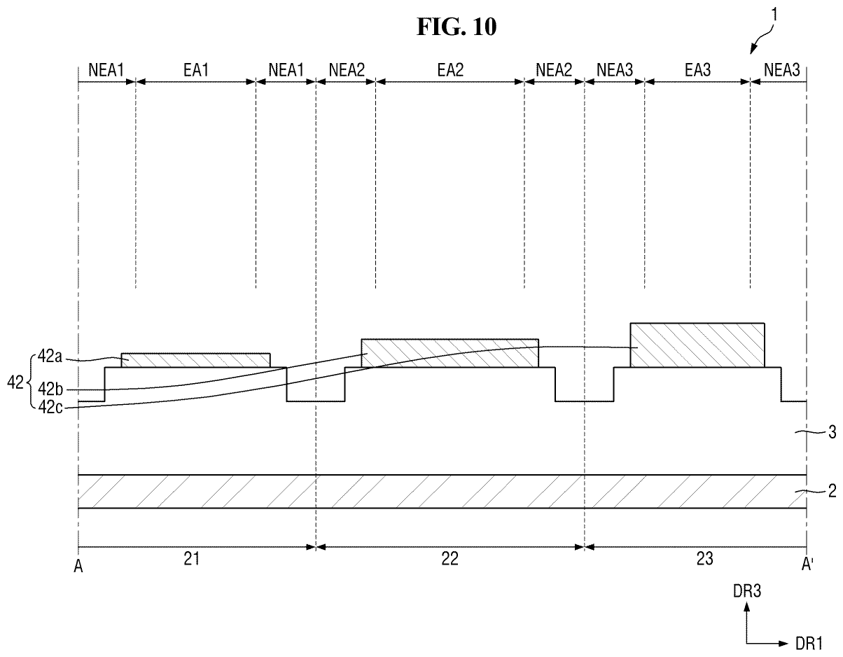

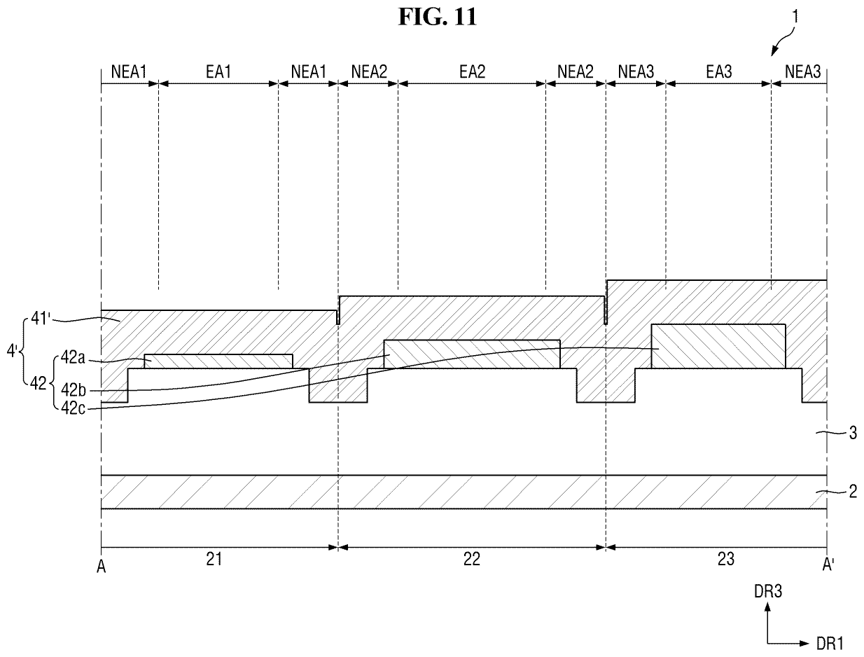

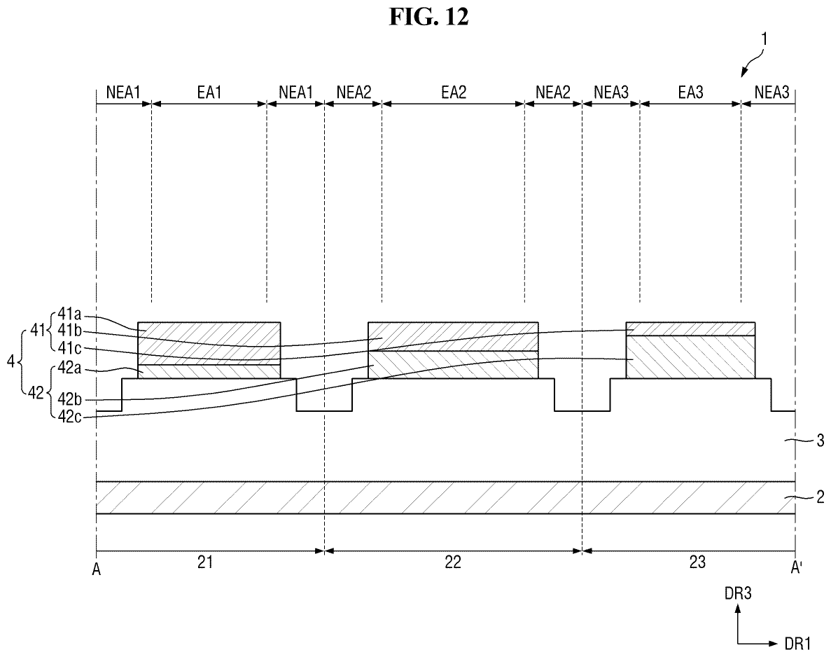

FIGS. 7 to 12 are cross-sectional views for each process of a method of manufacturing a display apparatus according to one or more embodiments of the present disclosure.

Referring to FIGS. 2, 3, and 7, an insulating layer 3′ is formed on the substrate 2.

The substrate 2 can be formed of a transparent material or an opaque material. The first sub-pixel 21, the second sub-pixel 22, and the third sub-pixel 23 are provided on the substrate 2. The first sub-pixel 21 can be provided to emit red (R) light, the second sub-pixel 22 can be provided to emit blue (B) light, and the third sub-pixel 23 can be provided to emit green (G) light.

The insulating layer 3′ can be disposed on the sub-pixel 21, 22, and 23. Circuit elements including a plurality of thin film transistors 31, 32, and 33 (see FIG. 3), various signal lines, capacitors, and the like are provided in the insulating layer 3′ of each sub-pixel 21, 22, or 23. The signal lines can include a gate line, a data line, a power line, and a reference line, and the thin film transistors 31, 32, and 33 can include a switching thin film transistor, a driving thin film transistor, and a sensing thin film transistor. Each of the sub-pixels 21, 22, and 23 is defined by an intersection structure of gate lines and data lines.

The insulating layer 3′ can protect the transistors 31, 32, and 33. The insulating layer 3′ can be formed of an inorganic insulating material, but is not necessarily limited thereto and can be formed of an organic insulating material.

The insulating layer 3′ can be formed of an inorganic material, such as silicon nitride (SiNₓ), silicon oxide (SiOₓ), aluminum oxide (Al₂O₃), etc., but the embodiments of the present disclosure are not limited thereto.

The first via hole VIA1 can be formed in the insulating layer 3′. The first via hole VIA1 can pass through the insulating layer 3′ in the thickness direction and can be electrically connected to the transistor 31, 32, or 33 of the sub-pixels 21, 22, or 23. The first via hole VIA1 can include a metal. For example, the first via hole VIA1 can include tungsten, but the embodiments of the present disclosure are not limited thereto. The first via hole VIA1 can be disposed on the emission areas EA1, EA2, and EA3.

Subsequently, as illustrated in FIGS. 2, 3, and 8, the first trench TRP1 is formed in the insulating layer 3. For example, the first trench TRP1 can be formed in the non-emission areas NEA1, NEA2, and NEA3. The first trench TRP1 can be formed to be recessed downward from an upper surface of the insulating layer 3. Accordingly, a thickness of the insulating layer 3 in which the first trench TRP1 is formed can be smaller than a thickness of the insulating layer 3 in which the first trench TRP1 is not formed.

Subsequently, as shown in FIGS. 2, 3, and 9, a reflective electrode layer 42′ is formed on the insulating layer 3. A thickness of the reflective electrode layer 42′ can be equal to the thickness of the third reflective electrode 42c of FIG. 2, but the embodiments of the present disclosure are not limited thereto. The reflective electrode layer 42′ can include a reflective material for reflecting light. For example, the reflective material can be a metal, but is not necessarily limited thereto, and can be any other material as long as it can reflect light. For example, the reflective material can include aluminum (Al) or silver (Ag), but the embodiments of the present disclosure are not limited thereto.

Subsequently, as illustrated in FIGS. 2, 3, and 10, the reflective electrodes 42 (42a, 42b, and 42c) separated for each sub-pixel 21, 22, or 23 are formed. The reflective electrodes 42 (42a, 42b, and 42c) can be formed through a photolithography process using a half tone mask. The reflective electrodes 42a, 42b, and 42c can reflect light, which is emitted toward the reflective electrode 42 among light emitted from the common light-emitting layer 5 of each sub-pixel 21, 22, or 23, toward the second electrode 6 or the encapsulation layer 8. In addition, the reflective electrode 42 is formed to implement the micro-cavity characteristic through reflection and re-reflection with the second electrode 6.

As illustrated in FIG. 3, the reflective electrodes 42a, 42b, and 42c can be electrically connected to the thin film transistors 31, 32, and 33 through the first via hole VIA1 in the areas in which the thin film transistors 31, 32, and 33 are disposed. The reflective electrodes 42a, 42b, and 42c can overlap the thin film transistors 31, 32, and 33 in the thickness direction, respectively. The thin film transistors 31, 32, and 33 can be disposed in the emission areas EA1, EA2, and EA3 of the sub-pixels 21, 22, and 23, respectively.

The reflective electrodes 42a, 42b, and 42c can have different thicknesses. For example, a thickness t1 of the first reflective electrode 42a can be smaller than a thickness t2 of the second reflective electrode 42b, and a thickness t3 of the third reflective electrode 42c can be larger than a thickness t2 of the second reflective electrode 42b.

Subsequently, as illustrated in FIGS. 2, 3, and 11, anode electrode layers 41′ are formed on the reflective electrodes 42a, 42b, and 42c. A thickness of the anode electrode layer 41′ can be equal to the thickness t4 of the first anode electrode 41a of FIG. 2, but the embodiments of the present disclosure are not limited thereto. For example, the anode electrode layer 41′ can include a transparent conductive material. For example, the anode electrode layer 41′ can include ITO, IZO, or TiN, but is not limited thereto.

Subsequently, as illustrated in FIGS. 2, 3, and 12, the anode electrodes 41 (41a, 41b, and 41c) are formed. The anode electrodes 41 (41a, 41b, and 41c) can be formed through a photolithography process using a half tone mask. The halftone mask for forming the anode electrodes 41 (41a, 41b, and 41c) can be the same as the halftone mask for forming the reflective electrodes 42a, 42b, and 42c, but the embodiments of the present disclosure are not limited thereto.

Hereinafter, a display apparatus according to another embodiment of the present disclosure will be described. In the description of the following embodiments, the detailed description of components that are the same as or similar to the components described in FIGS. 1 to 6 will be omitted or briefly discussed, or overlapping descriptions thereof will be omitted or briefly discussed.

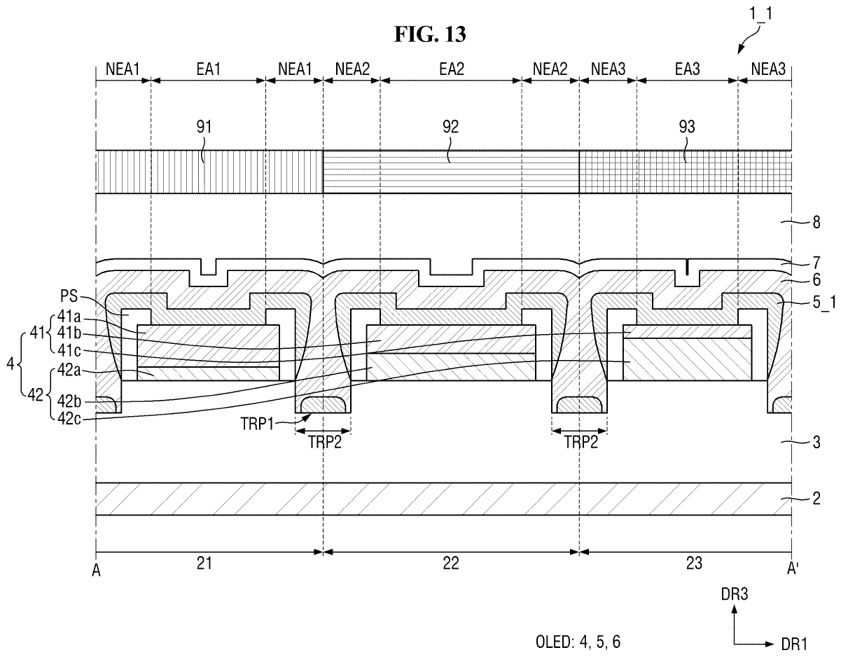

FIG. 13 is a cross-sectional view of a display apparatus according to another embodiment of the present disclosure.

Referring to FIG. 13, a display apparatus 1_1 according to the present embodiment differs from the display apparatus 1 according to FIG. 2 in that it includes a common light-emitting layer 5_1.

More specifically, the common light-emitting layer 5_1 can be physically separated at the boundaries between adjacent sub-pixels 21, 22, and 23.

For example, the common light-emitting layer 5_1 can be physically separated in the non-emission areas NEA1, NEA2, and NEA3. The common light-emitting layer 5_1 can be physically separated in the non-emission areas NEA1, NEA2, and NEA3 by the trenches TRP1 and TRP2.

For example, the common light-emitting layer 5_1 can be divided into a portion disposed on an outer surface of the bank PS of the non-emission area NEA1, NEA2, or NEA3 and a portion disposed on the upper surface of the insulating layer 3 in which the first trench TRP1 of the non-emission area NEA1, NEA2, or NEA3 is formed. The portion disposed on the outer surface of the bank PS of the non-emission area NEA1, NEA2, or NEA3 and the portion disposed on the upper surface of the insulating layer 3 in which the first trench TRP1 is formed can be physically separated.

According to the display apparatus 1_1 according to the present embodiment, a total of the thickness of the first trench TRP1 and the thickness of the second trench TRP2 can be maintained at the same level across the non-emission areas NEA1, NEA2, and NEA3. Accordingly, the common light-emitting layer 5_1 can be physically separated between the adjacent sub-pixels 21, 22, and 23, and the common light-emitting layer 5_1 can be physically separated at the same level in each non-emission area NEA1, NEA2, or NEA3. Accordingly, it is possible to reduce the LLC due to the common light-emitting layer 5_1.

Since the remaining parts have been described above with reference to FIGS. 2 to 4, the detailed description thereof will be omitted below.

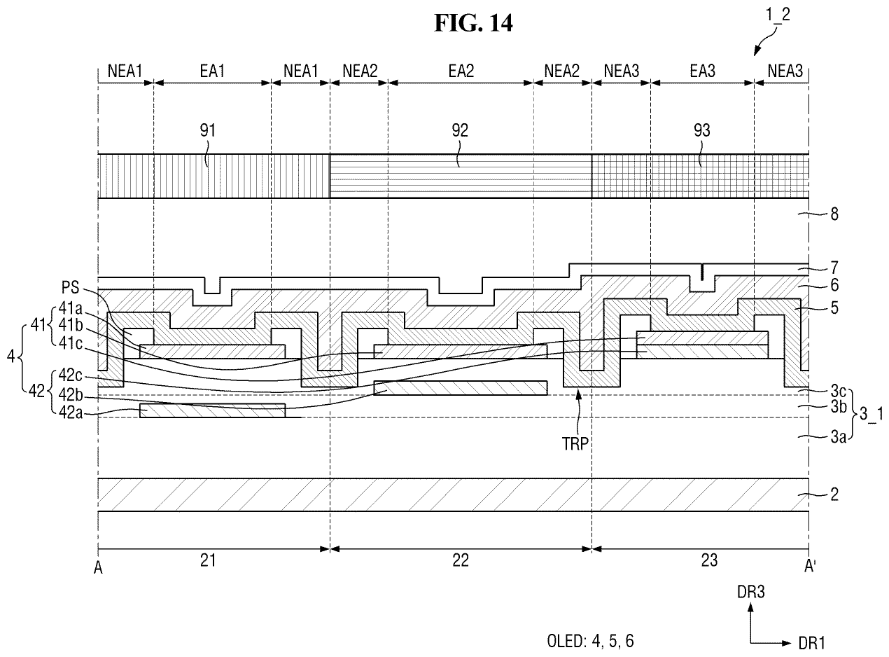

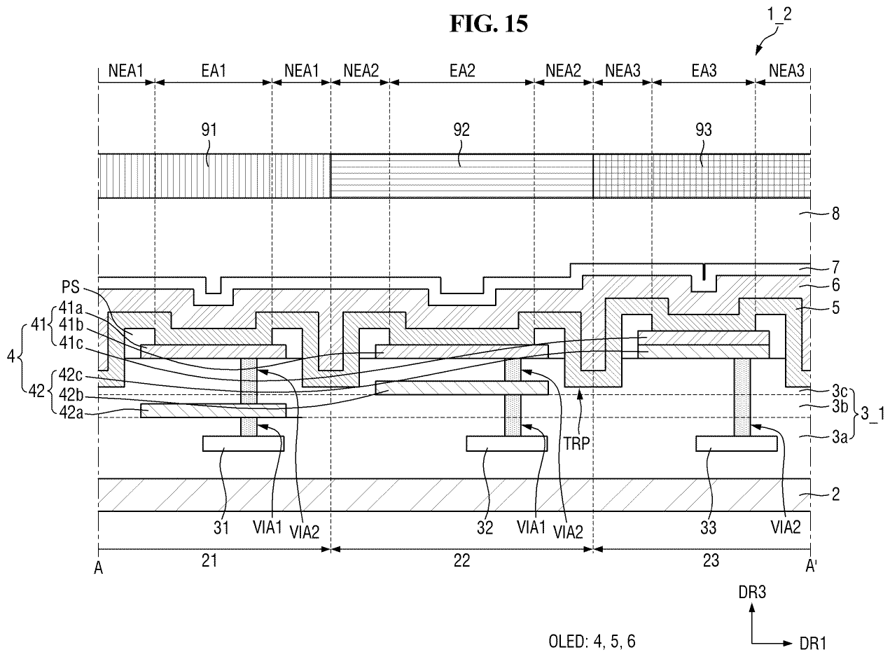

FIG. 14 is a cross-sectional view of the display apparatus according to still another embodiment of the present disclosure. FIG. 15 is a cross-sectional view of the display apparatus according to still another embodiment of the present disclosure.

Referring to FIGS. 14 and 15, a display apparatus 1_2 according to the present embodiment differs from the display apparatus 1 according to FIGS. 2 and 3 in that it includes an insulating layer 3_1 and the reflective electrodes 42a, 42b, and 42c are located on different layers.

More specifically, the insulating layer 3_1 can include first to third insulating layers 3a, 3b, and 3c.

The first insulating layer 3a can be disposed between the substrate 2 and the first reflective electrode 42a. The first insulating layer 3a can be formed of an inorganic material, such as silicon nitride (SiNₓ), silicon oxide (SiOₓ), aluminum oxide (Al₂O₃), etc., but the embodiments of the present disclosure are not limited thereto.

The first reflective electrode 42a can be disposed on the first insulating layer 3a.

The second insulating layer 3b can be disposed on the first reflective electrode 42a.

The second insulating layer 3b can be formed of an inorganic material, such as silicon nitride (SiNₓ), silicon oxide (SiOₓ), aluminum oxide (Al₂O₃), etc., but the embodiments of the present disclosure are not limited thereto. The second insulating layer 3b can cover the first reflective electrode 42a.

The second reflective electrode 42b can be disposed on the second insulating layer 3b.

The third insulating layer 3c can be disposed on the second reflective electrode 42b.

The third insulating layer 3c can be formed of an inorganic material, such as silicon nitride (SiNₓ), silicon oxide (SiOₓ), aluminum oxide (Al₂O₃), etc., but the embodiments of the present disclosure are not limited thereto. The third insulating layer 3c can cover the second reflective electrode 42b.

The third reflective electrode 42c can be disposed on the third insulating layer 3c.

The first trench TRP1 can be formed in the insulating layer 3_1. For example, the first trench TRP1 can be formed in the non-emission areas NEA1, NEA2, and NEA3. The first trench TRP1 can be formed to be recessed downward from an upper surface of the insulating layer 3_1. Accordingly, a thickness of the insulating layer 3_1 in which the first trench TRP1 is formed can be smaller than a thickness of the insulating layer 3_1 in which the first trench TRP1 is not formed.

The first via hole VIA1 can be formed in the insulating layer 3_1. The first via hole VIA1 can pass through the insulating layer 3_1 in the thickness direction and can be electrically connected to the transistor 31, 32, and 33 of the sub-pixel 21, 22, or 23. The first via hole VIA1 can include a metal. For example, the first via hole VIA1 can include tungsten, but the embodiments of the present disclosure are not limited thereto. The first via hole VIA1 can be disposed on the emission areas EA1, EA2, and EA3.

The reflective electrodes 42a, 42b, and 42c can reflect light, which is emitted toward the reflective electrode 42 among light emitted from the common light-emitting layer 5 of each sub-pixel 21, 22, or 23, toward the second electrode 6 or the encapsulation layer 8. In addition, the reflective electrode 42 is formed to implement the micro-cavity characteristic through reflection and re-reflection with the second electrode 6. To this end, the reflective electrode 42 can include a reflective material for reflecting light. For example, the reflective material can be a metal, but is not necessarily limited thereto, and can be any other material as long as it can reflect light. For example, the reflective material can include aluminum (Al) or silver (Ag), but the embodiments of the present disclosure are not limited thereto. Since the reflective electrode 42 is disposed at a relatively lower location than the common light-emitting layer 5 for emitting light, the reflective electrode 42 can reflect the light emitted from the common light-emitting layer 5 upward. Here, upward can refer to a direction in which a user can perceive light, for example, a side to which the encapsulation layer 8 or the color filter layer 9 is disposed. Accordingly, it is possible to further increase the light efficiency of the first sub-pixel 21, the second sub-pixel 22, and the third sub-pixel 23 compared to a case in which there is no reflective electrode 42, and the user can perceive an image with high brightness, for example, clear image, through the increased light efficiency. For example, the user can perceive a clear image.

A distance between the first reflective electrode 42a and the second electrode 6 can be longer than a distance between the second reflective electrode 42b and the second electrode 6. A distance between the second reflective electrode 42b and the second electrode 6 can be longer than a distance between the third reflective electrode 42c and the second electrode 6.

The reason why the reflective electrodes 42a, 42b, and 42c are formed to have various spacing distances (or resonance distances) from the second electrode 6 is that the light extraction efficiency of different colors can be increased through reflection and re-reflection between the reflective electrodes 42a, 42b, and 42c and the second electrode 6 according to the spacing distances. Accordingly, it is possible to increase the light extraction efficiency of red light in the first sub-pixel 21, increase the light extraction efficiency of green light in the second sub-pixel 22, and increase the light extraction efficiency of blue light in the third sub-pixel 23.

The anode electrodes 41a, 41b, and 41c can be disposed on the reflective electrodes 42a, 42b, and 42c, respectively. The first anode electrode 41a and the first reflective electrode 42a can be spaced apart from each other, the second anode electrode 41b and the second reflective electrode 42b can be spaced apart from each other, and the third anode electrode 41c can come into direct contact with an upper surface of the third reflective electrode 42c.

As illustrated in FIG. 15, the first anode electrodes 41a and 41b and the first reflective electrodes 42a and 42b can be electrically connected through second via holes VIA2. The second via hole VIA2 can include a metal. For example, the second via hole VIA2 can include tungsten, but the embodiments of the present disclosure are not limited thereto. The second via hole VIA2 can be disposed on the emission areas EA1, EA2, and EA3.

Even in the case of the display apparatus 1_2, it is possible to expand the emission areas EA1, EA2, and EA3 of the sub-pixels 21, 22, and 23 by expanding the emission areas EA1, EA2, and EA3 of the sub-pixels 21, 22, and 23 to the areas in which the thin film transistors 31, 32, and 33 are disposed. To expand the emission areas EA1, EA2, and EA3 of the sub-pixels 21, 22, and 23, in the first sub-pixel 21, conductive layers on which the second and third reflective electrodes 42b and 42c are disposed may not be disposed; in the second sub-pixel 22, conductive layers on which the first and third reflective electrodes 42a and 42c are disposed may not be disposed; and in the third sub-pixel 23, conductive layers on which the first and second reflective electrodes 42a and 42b are disposed may not be disposed.

Accordingly, the micro-cavity characteristic between the reflective electrodes 42a, 42b, and 42c and the second electrode 6 can be maintained even in the emission areas EA1, EA2, and EA3 of the areas in which the thin film transistors 31, 32, and 33 are disposed.

For example, in the first emission area EA1, no metals located on the same layer as the second reflective electrode 42b and the third reflective electrode 42c can be disposed; in the second emission area EA2, no metals located on the same layer as the first reflective electrode 42a and the third reflective electrode 42c can be disposed; and in the third emission area EA3, no metals located on the same layer as the first reflective electrode 42a and the second reflective electrode 42b can be disposed.

Since the remaining parts have been described above with reference to FIGS. 2 and 3, the detailed description thereof will be omitted below.

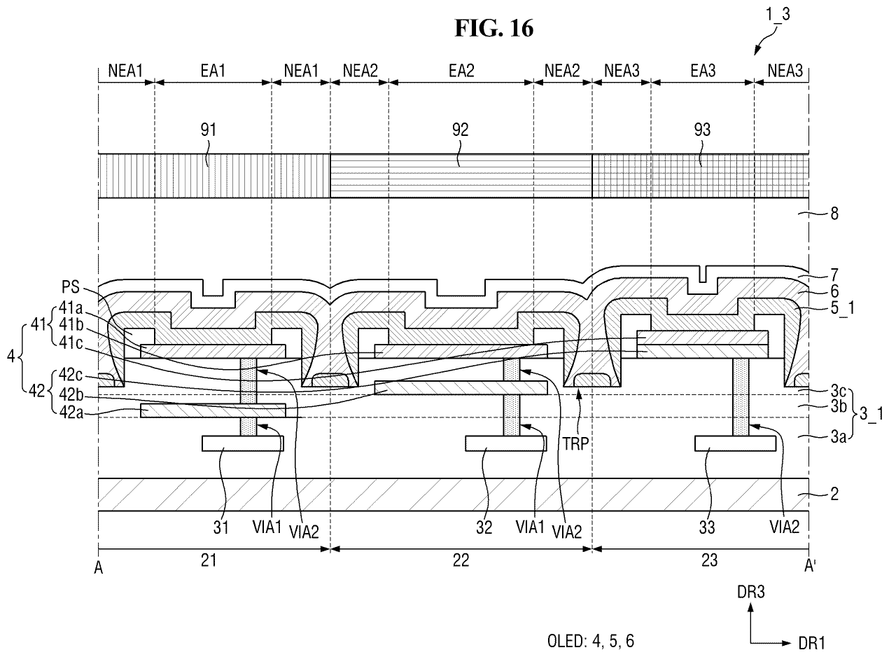

FIG. 16 is a cross-sectional view of a display apparatus according to yet another embodiment of the present disclosure.

Referring to FIG. 16, a display apparatus 1_3 according to the present embodiment differs from the display apparatus 1_2 according to FIG. 13 in that it includes the common light-emitting layer 5_1.

More specifically, the common light-emitting layer 5_1 can be physically separated at the boundaries between adjacent sub-pixels 21, 22, and 23.

For example, the common light-emitting layer 5_1 can be physically separated in the non-emission areas NEA1, NEA2, and NEA3. The common light-emitting layer 5_1 can be physically separated in the non-emission areas NEA1, NEA2, and NEA3 by the trenches TRP1 and TRP2.

For example, the common light-emitting layer 5_1 can be divided into a portion disposed on an outer surface of the bank PS of the non-emission area NEA1, NEA2, or NEA3 and a portion disposed on the upper surface of the insulating layer 3 in which the first trench TRP1 of the non-emission area NEA1, NEA2, or NEA3 is formed. The portion disposed on the outer surface of the bank PS of the non-emission area NEA1, NEA2, or NEA3 and the portion disposed on the upper surface of the insulating layer 3 in which the first trench TRP1 is formed can be physically separated.

Accordingly, it is possible to reduce the LLC due to the common light-emitting layer 5_1.

Since the remaining parts have been described above with reference to FIGS. 2 to 4, 14, and 15, the detailed description thereof will be omitted below.

A display apparatus according to various embodiments of the present disclosure can be described as follows.

According to various embodiments of the present disclosure, there is provided a display apparatus including a substrate including a first sub-pixel, a second sub-pixel, and a third sub-pixel, a reflective electrode layer including a first reflective electrode of the first sub-pixel, a second reflective electrode of the second sub-pixel, and a third reflective electrode of the third sub-pixel, and an anode electrode layer including a first anode electrode of the first sub-pixel, a second anode electrode of the second sub-pixel, and a third anode electrode of the third sub-pixel, in which a total thickness of the first reflective electrode and the first anode electrode is equal to each of a total thickness of the second reflective electrode and the second anode electrode and a total thickness of the third reflective electrode and the third anode electrode.

In the display apparatus according to various embodiments of the present disclosure, the first anode electrode can come into direct contract with the first reflective electrode, the second anode electrode can come into direct contract with the second reflective electrode, and the third anode electrode can come into direct contract with the third reflective electrode.

In the display apparatus according to various embodiments of the present disclosure, the thickness of the first anode electrode can be smaller than the thickness of the second anode electrode, and the thickness of the second anode electrode can be smaller than a thickness of the third anode electrode.

In the display apparatus according to various embodiments of the present disclosure, the thickness of the first reflective electrode can be larger than the thickness of the second reflective electrode, and the thickness of the second reflective electrode can be larger than the thickness of the third reflective electrode.

The display apparatus according to various embodiments of the present disclosure can further include a thin film transistor layer between the substrate and the reflective electrode layer, in which the thin film transistor layer can include a first thin film transistor of the first sub-pixel, a second thin film transistor of the second sub-pixel, and a third thin film transistor of the third sub-pixel, the first thin film transistor can be connected to the first reflective electrode through a first via hole, the second thin film transistor can be connected to the second reflective electrode through the first via hole, and the third thin film transistor can be connected to the third reflective electrode through the first via hole.

The display apparatus according to various embodiments of the present disclosure can further include a bank on the anode electrode layer, in which the bank can cover a first non-emission area of the first anode electrode, expose a first emission area of the first anode electrode, cover a second non-emission area of the second anode electrode, expose a second emission area of the second anode electrode, cover a third non-emission area of the third anode electrode, and expose a third emission area of the third anode electrode, the first emission area can overlap the first thin film transistor, the second emission area can overlap the second thin film transistor, and the third emission area can overlap the third thin film transistor.

The display apparatus according to various embodiments of the present disclosure can further include an insulating layer that surrounds the thin film transistor layer and disposed between the substrate and the reflective electrode layer, in which the insulating layer can have a trench in each of the first non-emission area, the second non-emission area, and the third non-emission area.

The display apparatus according to various embodiments of the present disclosure can further include a common light-emitting layer disposed on the banks of the first sub-pixel to the third sub-pixel, in which the common light-emitting layer can be physically separated in the trench.

The display apparatus according to various embodiments of the present disclosure can further include a cathode electrode on the common light-emitting layer, in which a distance between the first reflective electrode and the cathode electrode can be larger than a distance between the second reflective electrode and the cathode electrode, and a distance between the second reflective electrode and the cathode electrode can be larger than a distance between the third reflective electrode and the cathode electrode.

According to various embodiments of the present disclosure, there is provided a display apparatus including a substrate in which a first sub-pixel having a first emission area and a first non-emission area is defined, an insulating layer on the substrate, a first thin film transistor of the first sub-pixel inside the insulating layer, a first reflective electrode of the first sub-pixel on the insulating layer, a first anode electrode of the first sub-pixel on the first reflective electrode, and a bank disposed in the first non-emission area on the first anode electrode, in which the first thin film transistor is disposed in the first emission area.

In the display apparatus according to various embodiments of the present disclosure, the first thin film transistor can be electrically connected to the first reflective electrode.

In the display apparatus according to various embodiments of the present disclosure, the first anode electrode can come into direct contact with the first reflective electrode.

In the display apparatus according to various embodiments of the present disclosure, the insulating layer can have a trench formed in the first non-emission area.

The display apparatus according to various embodiments of the present disclosure can further include a common light-emitting layer disposed on the bank, in which the common light-emitting layer can be physically separated in the trench.

The display apparatus according to various embodiments of the present disclosure can further include a second sub-pixel including a second emission area and a second non-emission area, in which the second sub-pixel can include a second thin film transistor, a second reflective electrode electrically connected to the second thin film transistor, and a second anode electrode on the second reflective electrode, and the first reflective electrode and the second reflective electrode can be located on different layers.

In the display apparatus according to various embodiments of the present disclosure, the insulating layer can include a first insulating layer between the substrate and the first reflective electrode and a second insulating layer between the first reflective electrode and the second reflective electrode.

In the display apparatus according to various embodiments of the present disclosure, the bank can be disposed in the second non-emission area of the second anode electrode, and the second thin film transistor can be disposed in the second emission area.

The display apparatus according to various embodiments of the present disclosure can further include a third sub-pixel including a third emission area and a third non-emission area, in which the third sub-pixel can include a third thin film transistor, a third reflective electrode electrically connected to the third thin film transistor, and a third anode electrode on the third reflective electrode, and the second reflective electrode and the third reflective electrode can be located on different layers.

In the display apparatus according to various embodiments of the present disclosure, the insulating layer can further include a third insulating layer between the second reflective electrode and the third reflective electrode.

In the display apparatus according to various embodiments of the present disclosure, the bank can be further disposed in the third non-emission area of the third anode electrode, and the third thin film transistor can be disposed in the third emission area.

According to the embodiments of the present disclosure, it is possible to reduce a lateral leakage current by equally maintaining the depth of the trench of each sub-pixel and separating the common light-emitting layer.

According to the embodiments of the present disclosure, it is possible to equally maintain the depth of the trench of each sub-pixel by equally maintaining the thickness of the reflective electrode and the thickness of the anode electrode of each pixel.

According to the embodiments of the present disclosure, it is possible to expand the emission area of each sub-pixel by expanding the emission area of each sub-pixel to the area in which the transistor is disposed.

According to the embodiment of the present disclosure s, it is possible to have the micro-cavity characteristic by adjusting the thicknesses of the reflective electrode and the anode electrode of each sub-pixel.

According to the embodiments of the present disclosure, it is possible to increase the light efficiency of the display apparatus by expanding the emission area of each sub-pixel.

However, effects obtainable from the present disclosure are not limited to the above-described effects, and other effects that are not mentioned will be able to be clearly understood by those skilled in the art to which the present disclosure pertains from the following description.

Although the embodiments have been described above with reference to the accompanying drawings, those skilled in the art to which the present disclosure pertains will be able to understand that the above-described technical configuration can be carried out in other specific forms without changing the technical spirit or essential features thereof. Accordingly, it should be understood that the above-described embodiments are illustrative and not restrictive in all respects. In addition, the scope of the embodiments is determined by the appended claims rather than detailed description. In addition, the meaning and scope of the claims and all changed or modified forms derived from the equivalent concept thereof should be construed as being included in the scope of the embodiments.

### DESCRIPTION OF REFERENCE NUMERALS

1: display apparatus
2: substrate
3: insulating layer
4: first electrode
5: common light-emitting layer
6: second electrode
7: capping layer
8: encapsulation layer
9: color filter layer
PS: bank

What is claimed is:

1. A display apparatus comprising:
a substrate including a first sub-pixel, a second sub-pixel, and a third sub-pixel;
a reflective electrode layer including a first reflective electrode of the first sub-pixel, a second reflective electrode of the second sub-pixel, and a third reflective electrode of the third sub-pixel; and
an anode electrode layer including a first anode electrode of the first sub-pixel, a second anode electrode of the second sub-pixel, and a third anode electrode of the third sub-pixel,
wherein a total thickness of the first reflective electrode and the first anode electrode is equal to a total thickness of the second reflective electrode and the second anode electrode, and is equal to a total thickness of the third reflective electrode and the third anode electrode.

2. The display apparatus of claim 1, wherein the first anode electrode comes into direct contract with the first reflective electrode, the second anode electrode comes into direct contract with the second reflective electrode, and the third anode electrode comes into direct contract with the third reflective electrode.

3. The display apparatus of claim 2, wherein a thickness of the first anode electrode is smaller than a thickness of the second anode electrode, and the thickness of the second anode electrode is smaller than a thickness of the third anode electrode.

4. The display apparatus of claim 3, wherein a thickness of the first reflective electrode is larger than a thickness of the second reflective electrode, and the thickness of the second reflective electrode is larger than a thickness of the third reflective electrode.

5. The display apparatus of claim 1, further comprising a thin film transistor layer between the substrate and the reflective electrode layer,
wherein the thin film transistor layer includes a first thin film transistor of the first sub-pixel, a second thin film transistor of the second sub-pixel, and a third thin film transistor of the third sub-pixel, and
wherein the first thin film transistor is connected to the first reflective electrode through a first via hole, the second thin film transistor is connected to the second reflective electrode through the first via hole, and the third thin film transistor is connected to the third reflective electrode through the first via hole.

6. The display apparatus of claim 5, further comprising a bank on the anode electrode layer,
wherein the bank covers a first non-emission area of the first anode electrode, exposes a first emission area of the first anode electrode, covers a second non-emission area of the second anode electrode, exposes a second emission area of the second anode electrode, covers a third non-emission area of the third anode electrode, and exposes a third emission area of the third anode electrode, and
wherein the first emission area overlaps the first thin film transistor, the second emission area overlaps the second thin film transistor, and the third emission area overlaps the third thin film transistor.

7. The display apparatus of claim 6, further comprising an insulating layer that surrounds the thin film transistor layer and disposed between the substrate and the reflective electrode layer,
wherein the insulating layer has a trench in each of the first non-emission area, the second non-emission area, and the third non-emission area.

8. The display apparatus of claim 7, further comprising a common light-emitting layer disposed on the bank corresponding to the first, second and third sub-pixels,
wherein the common light-emitting layer is physically separated in the trench.

9. The display apparatus of claim 8, further comprising a cathode electrode on the common light-emitting layer,
wherein a distance between the first reflective electrode and the cathode electrode is larger than a distance between the second reflective electrode and the cathode electrode, and a distance between the second reflective electrode and the cathode electrode is larger than a distance between the third reflective electrode and the cathode electrode.

10. A display apparatus comprising:
a substrate including a first sub-pixel having a first emission area and a first non-emission area;
an insulating layer on the substrate;
a first thin film transistor of the first sub-pixel inside the insulating layer;
a first reflective electrode of the first sub-pixel on the insulating layer;
a first anode electrode of the first sub-pixel on the first reflective electrode; and
a bank disposed in the first non-emission area on the first anode electrode,
wherein the first thin film transistor is disposed in the first emission area.

11. The display apparatus of claim 10, wherein the first thin film transistor is electrically connected to the first reflective electrode, and the first anode electrode is electrically connected to the first reflective electrode.

12. The display apparatus of claim 11, wherein the insulating layer has a trench formed in the first non-emission area.

13. The display apparatus of claim 12, further comprising a common light-emitting layer disposed on the bank,
wherein the common light-emitting layer is physically separated in the trench.

14. The display apparatus of claim 11, further comprising a second sub-pixel including a second emission area and a second non-emission area,
wherein the second sub-pixel includes a second thin film transistor, a second reflective electrode electrically connected to the second thin film transistor, and a second anode electrode on the second reflective electrode, and
wherein the first reflective electrode and the second reflective electrode are located on different layers, and a metal located on the same layer as the first reflective electrode is not disposed in the second emission area.

15. The display apparatus of claim 14, wherein the insulating layer includes:
a first insulating layer between the substrate and the first reflective electrode, and
a second insulating layer between the first reflective electrode and the second reflective electrode.

16. The display apparatus of claim 15, wherein the bank is disposed in the second non-emission area of the second anode electrode, and the second thin film transistor is disposed in the second emission area.

17. The display apparatus of claim 16, further comprising a third sub-pixel including a third emission area and a third non-emission area,
wherein the third sub-pixel includes a third thin film transistor, a third reflective electrode electrically connected to the third thin film transistor, and a third anode electrode on the third reflective electrode, and
wherein the third reflective electrode is located on a different layer from each of the second reflective electrode and the first reflective electrode, and a metal located on the same layer as the first reflective electrode and the second reflective electrode is not disposed in the third emission area.

18. The display apparatus of claim 17, wherein the insulating layer further includes a third insulating layer between the second reflective electrode and the third reflective electrode.

19. The display apparatus of claim 18, wherein the bank is further disposed in the third non-emission area of the third anode electrode, and the third thin film transistor is disposed in the third emission area.
